(19) United States
(12) Patent Application Publication
(10) Pub. No.: US 2025/0030398 A1
(43) Pub. Date: Jan. 23, 2025

(54) ACOUSTIC WAVE DEVICE AND MANUFACTURING METHOD FOR ACOUSTIC WAVE DEVICE

(71) Applicant: Murata Manufacturing Co., Ltd., Nagaokakyo-shi (JP)

(72) Inventor: Kazuki YAMAMORI, Nagaokakyo-shi (JP)

(21) Appl. No.: 18/631,583

(22) Filed: Apr. 10, 2024

(30) Foreign Application Priority Data
Jul. 20, 2023 (JP) 2023-118483

(51) Int. Cl. H03H 9/05; H03H 3/08; H03H 9/02; H03H 9/10; H03H 9/25

(52) U.S. Cl. CPC H03H 9/059; H03H 3/08; H03H 9/02992; H03H 9/1085; H03H 9/25

(57) ABSTRACT

An acoustic wave device includes a piezoelectric substrate including first and second main surfaces, a mounting substrate including third and fourth main surfaces, a functional electrode on the first main surface to perform electromechanical conversion with the piezoelectric substrate, first and second plane electrodes on the first main surface and connected to the functional electrode, and a third plane electrode on the first main surface and in contact with an end side of the piezoelectric substrate, and not connected to the functional electrode and the plane electrode, and bump electrodes bonded to the first and third main surfaces. A maximum distance D13ₘₐₓ between two end portions of the third plane electrode is smaller than a minimum distance D1ₘᵢₙ of distances between two of the first and second plane electrodes having different potentials from each other.

### CROSS REFERENCE TO RELATED APPLICATIONS

This application claims the benefit of priority to Japanese Patent Application No. 2023-118483 filed on Jul. 20, 2023. The entire contents of this application are hereby incorporated herein by reference.

### BACKGROUND OF THE INVENTION

### 1. Field of the Invention

The present invention relates to acoustic wave devices and manufacturing methods for acoustic wave devices.

### 2. Description of the Related Art

International Publication No. 2021/100505 discloses a structure of an acoustic wave device having a wafer level package (WLP) structure. The above-described acoustic wave device is manufactured in such a manner that a collective board in which a functional electrode and a wiring electrode are formed is divided into a plurality of individual chips through cutting with a dicing machine, and the chips are face-down bonded to a mounting substrate. In the collective board, a measurement electrode for inspecting characteristics in a state of the collective board is formed on a dicing line, and the measurement electrode is divided into the functional electrode and the wiring electrode through the cutting with the dicing machine, and has no potential.

### SUMMARY OF THE INVENTION

However, in the acoustic wave device disclosed in International Publication No. 2021/100505, the measurement electrodes have no potential after cutting with a dicing machine. However, when the measurement electrodes are separated or isolated through a dicing process, the measurement electrode rides over and comes into contact with a plurality of electrodes having different potentials, thereby causing a possibility of a short-circuit defect.

Therefore, example embodiments of the present invention provide acoustic wave devices and manufacturing methods for acoustic wave devices, in which a short-circuit defect is reduced or prevented.

According to an aspect of an example embodiment of the present invention, an acoustic wave device includes.

In addition, according to another aspect of an example embodiment of the present invention, an acoustic wave device includes.

In addition, according to still another aspect of an example embodiment of the present invention, a manufacturing method for an acoustic wave device includes.

According to example embodiments of the present invention, a short-circuit defect of an acoustic wave device can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a plan view of an acoustic wave chip according to an example embodiment of the present invention.

FIG. 1B is a plan view of a mounting substrate according to an example embodiment of the present invention.

FIG. 1C is a sectional view of an acoustic wave device according to an example embodiment of the present invention.

FIG. 2A is a plan view and a sectional view schematically showing a first example of an acoustic wave resonator of an acoustic wave device according to an example embodiment of the present invention.

FIG. 2B is a sectional view schematically showing a second example of an acoustic wave resonator of an acoustic wave device according to an example embodiment of the present invention.

FIG. 2C is a sectional view schematically showing a third example of an acoustic wave resonator of an acoustic wave device according to an example embodiment of the present invention.

FIG. 3 is a flowchart showing a manufacturing method for an acoustic wave device according to an example embodiment of the present invention.

FIG. 4 is a plan view of a collective board according to an example embodiment of the present invention.

FIGS. 5A and 5B are views showing a plane electrode in the vicinity of a dicing line of the collective board and a configuration of a plane electrode in the vicinity of an end side of an acoustic wave chip according to an example embodiment of the present invention.

FIG. 6 is a plan view of a collective board according to a comparative example.

### DETAILED DESCRIPTION OF THE EXAMPLE EMBODIMENTS

Hereinafter, example embodiments of the present disclosure will be described in detail with reference to the drawings. All of the example embodiments described below represent comprehensive or specific examples. Numerical values, shapes, materials, configuration elements, or dispositions and connection structures of the configuration elements which are described in the following example embodiments are merely examples, and are not intended to limit the present invention. In the configuration elements in the following example embodiments, configuration elements which are not described in an independent claim will be described as optional configuration elements. In addition, sizes or size ratios of the configuration elements shown in drawings are not necessarily exact.

Each drawing is a schematic view in which emphasis, omission, or ratio adjustment is made as appropriate to represent example embodiments of the present invention, and is not necessarily shown strictly. In some cases, a shape, a positional relationship, and a ratio may be different from actual ones. In the drawings, the same reference numerals are assigned to substantially the same configurations, and repeated description thereof may be omitted or simplified in some cases.

In a circuit configuration of the present disclosure, a case of “being connected” includes not only a case where the configuration elements are directly connected by an electrode and/or a wiring conductor, but also a case where the configuration elements are electrically connected with a matching element such as an inductor and a capacitor, and a switch circuit interposed therebetween. A case of “being connected between A and B” means that the configuration elements are connected to both A and B between A and B.

In addition, terms representing a relationship between elements such as “parallel” and “perpendicular”, terms representing a shape of an element such as “rectangular”, and a numerical range not only represent strict meanings, but also include a substantially equivalent range, for example, that an error of approximately several percent is included.

### EXAMPLE EMBODIMENTS

### 1. Configuration of Acoustic Wave Device 1

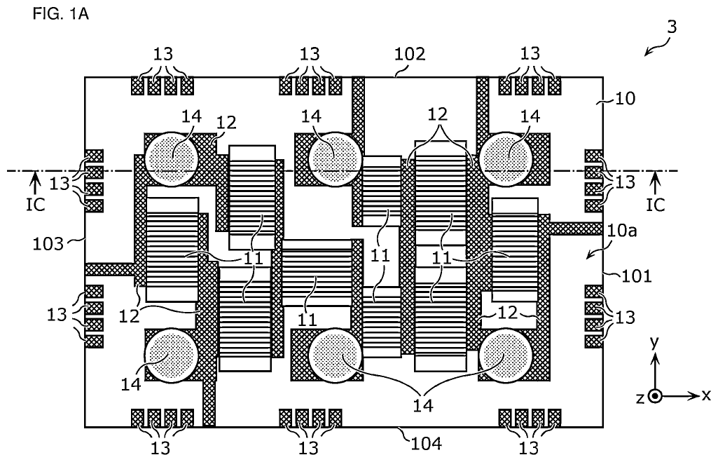

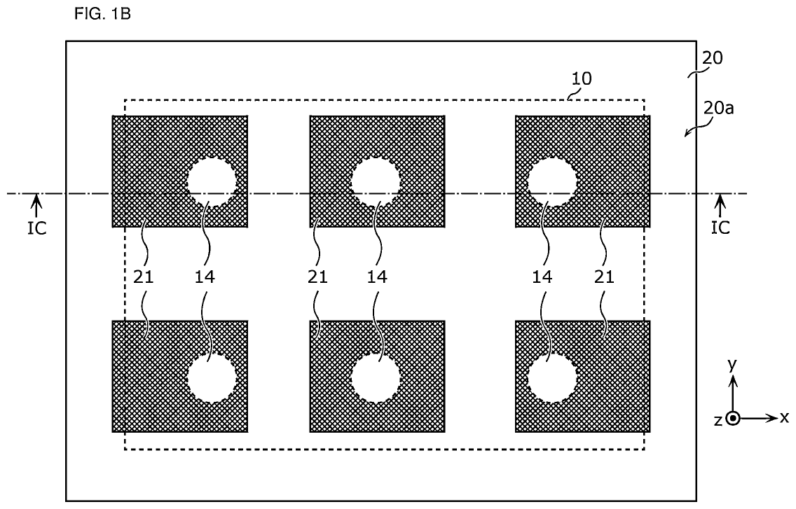

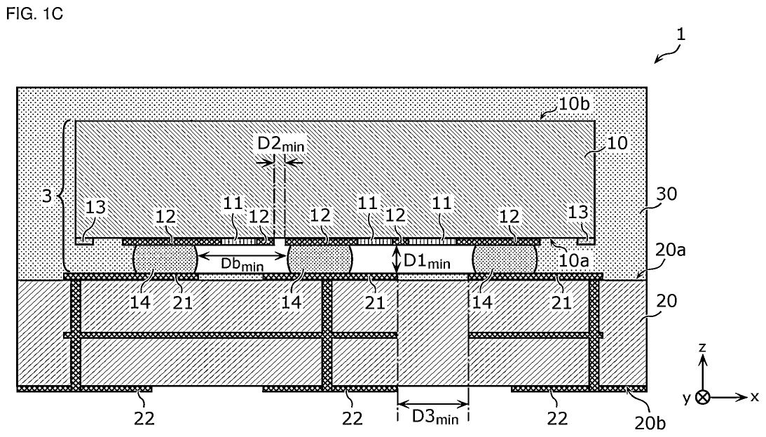

FIG. 1A is a plan view of an acoustic wave chip 3 according to an example embodiment. FIG. 1B is a plan view of a mounting substrate 20 according to the example embodiment shown in FIG. 1A. FIG. 1C is a sectional view of an acoustic wave device 1 according to the example embodiment shown in FIG. 1A. FIG. 1A is a perspective view when a main surface 10a side of a piezoelectric substrate 10 is viewed from a positive side of a z-axis, FIG. 1B is a perspective view when a main surface 20a side of the mounting substrate 20 is viewed from the positive side of the z-axis, and FIG. 1C is a sectional view taken along line IC-IC in FIGS. 1A and 1B.

As shown in FIG. 1C, the acoustic wave device 1 includes an acoustic wave chip 3, the mounting substrate 20, and a resin 30.

As shown in FIG. 1A, the acoustic wave chip 3 includes the piezoelectric substrate 10, a functional electrode 11, a plurality of plane electrodes 12, a plurality of plane electrodes 13, and a plurality of bump electrodes 14.

The piezoelectric substrate 10 is an example of a first substrate, has piezoelectricity, and includes a main surface 10a (first main surface) and a main surface 10b (second main surface).

The functional electrode 11 is provided on the main surface 10a, and performs electromechanical conversion with the piezoelectric substrate 10.

Each of the plurality of plane electrodes 12 is an example of a first plane electrode, is provided on the main surface 10a, and is connected to the functional electrode 11.

Each of the plurality of plane electrodes 13 is an example of a third plane electrode, as shown in FIG. 1A, is provided on the main surface 10a to be in contact with end sides 101, 102, 103, or 104 of the main surface 10a, and is not connected to the functional electrode 11 and the plane electrode 12. The plane electrode 13 is a portion of a stylus electrode to measure bandpass characteristics of the acoustic wave chip 3 in a state of a collective board 2 before the acoustic wave chips 3 are individualized.

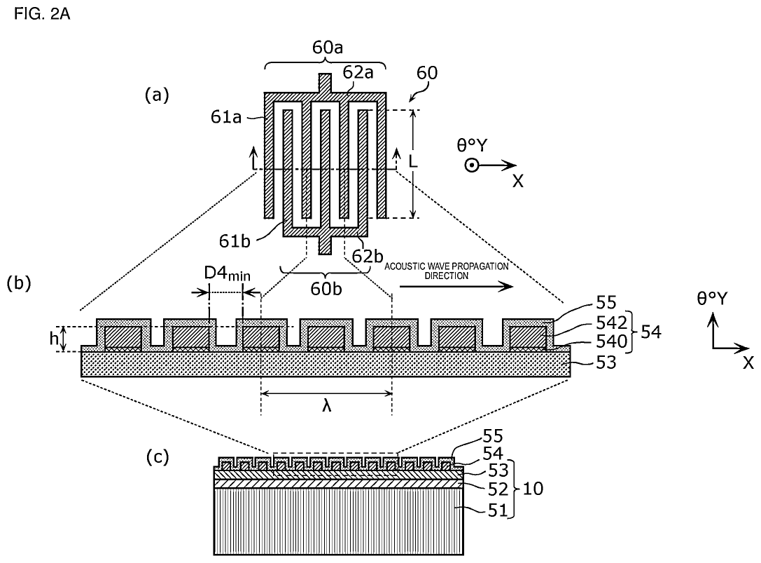

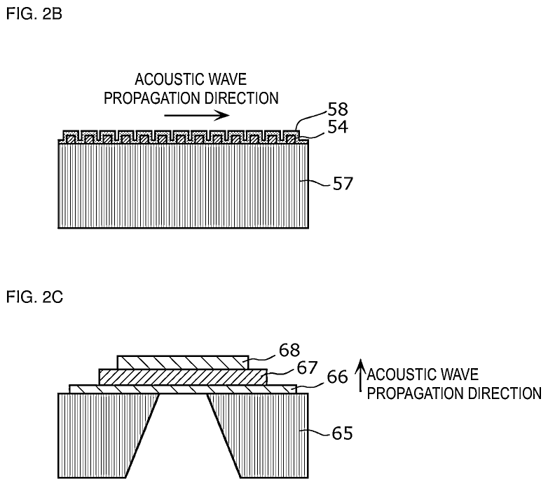

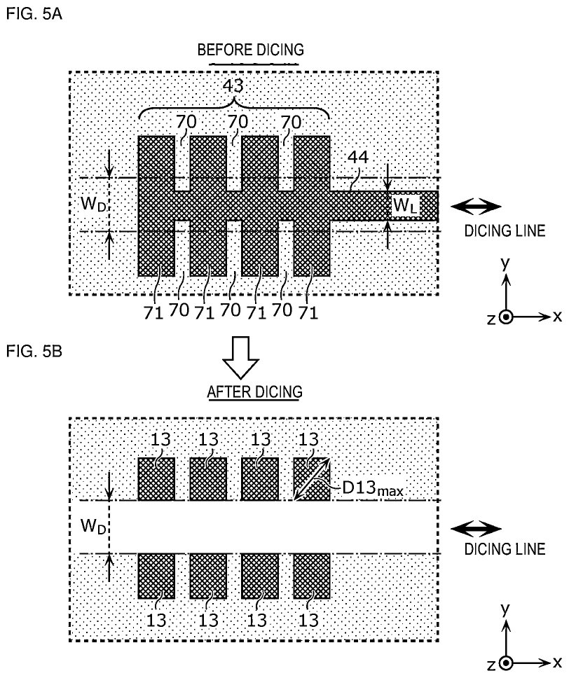

Detailed structures of the piezoelectric substrate 10, the functional electrode 11, and the plane electrode 12 will be described later with reference to FIGS. 2A and 2B. In addition, a detailed structure of the plane electrode 13 will be described later with reference to FIG. 5.

As shown in FIG. 1C, each of the plurality of bump electrodes 14 is connected to the main surface 10a and the main surface 20a. Each of the plurality of bump electrodes 14 may be directly bonded to the main surface 10a and the main surface 20a, or may be bonded to the main surface 10a with the plane electrode 12 interposed therebetween, and may be connected to the main surface 20a with the plane electrode 21 interposed therebetween. The bump electrode 14 is a ball-shaped electrode formed of highly conductive metal, and for example, a solder bump formed of Sn/Ag/Cu or a bump having Au as a main component may be used.

The mounting substrate 20 is an example of a second substrate. As shown in FIG. 1C, the mounting substrate 20 includes the main surface 20a (third main surface) and the main surface 20b (fourth main surface), and the main surface 20a faces the main surface 10a. The mounting substrate 20 and the acoustic wave chip 3 are face-down bonded by using the plurality of bump electrodes 14 so that the main surface 20a of the mounting substrate 20 and the main surface 10a of the piezoelectric substrate 10 face each other. As the mounting substrate 20, for example, a low temperature co-fired ceramics (LTCC) substrate having a multilayer structure of a plurality of dielectric layers, a high temperature co-fired ceramics (HTCC) substrate, a component incorporated substrate, a substrate having a redistribution layer (RDL), or a printed substrate may be used.

As shown in FIGS. 1B and 1C, the mounting substrate 20 includes a plurality of plane electrodes 21 and a plurality of plane electrodes 22.

Each of the plurality of plane electrodes 21 is an example of a second plane electrode, and is provided on the main surface 20a. Each of the plurality of plane electrodes 22 is provided on the main surface 20b. The plane electrode 21 and the plane electrode 22 are connected to each other by a via conductor inside the mounting substrate 20.

As shown in FIG. 1C, the resin 30 is positioned to be in contact with the main surface 20a and to cover the acoustic wave chip 3, and has a function of ensuring reliability in mechanical strength and humidity resistance of the acoustic wave chip 3. The resin 30 is not located in a region where the functional electrode 11 is located.

Here, a maximum distance D13ₘₐₓ (refer to FIG. 5B)) between two end portions of the plane electrode 13 is smaller than a minimum distance D1ₘᵢₙ (refer to FIG. 1C) of distances between one of the plurality of plane electrodes 12 and one of the plurality of plane electrodes 21 which have potentials different from each other.

The maximum distance D13ₘₐₓ between the two end portions of the plane electrode 13 is defined as the maximum distance of the distances between any two end portions inside one plane electrode 13 when the plane electrode 13 is viewed in a plan view.

According to the above-described configuration, even when the plane electrode 13 is separated or isolated from the piezoelectric substrate 10, the maximum distance D13ₘₐₓ of the plane electrode 13 is smaller than the minimum distance D1ₘᵢₙ. Therefore, it is possible to reduce or eliminate a possibility that the separated or isolated plane electrode 13 rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

In addition, the maximum distance D13ₘₐₓ (refer to FIG. 5B) between the two end portions of the plane electrode 13 may be smaller than the minimum distance Dbₘᵢₙ (refer to FIG. 1C) of the distances between the two bump electrodes 14 having different potentials in the plurality of bump electrodes 14.

According to this configuration, even when the plane electrode 13 is separated or isolated from the piezoelectric substrate 10, the maximum distance D13ₘₐₓ of the plane electrode 13 is smaller than the minimum distance Dbₘᵢₙ. Therefore, it is possible to reduce or eliminate a possibility that the separated or isolated plane electrode 13 rides over and comes into contact with the two bump electrodes 14 having different potentials. Therefore, it is possible to provide the acoustic wave device 1 in which the short-circuit defect is reduced or prevented.

In addition, it is preferable that the maximum distance D13ₘₐₓ (refer to FIG. 5B) between the two end portions of the plane electrode 13 is smaller than a minimum distance D3ₘᵢₙ (refer to FIG. 1C) of the distances between the two plane electrodes 21 having different potentials in the plurality of plane electrodes 21.

According to this configuration, even when the plane electrode 13 is separated or isolated from the piezoelectric substrate 10, the maximum distance D13ₘₐₓ of the plane electrode 13 is smaller than the minimum distance D3ₘᵢₙ. Therefore, it is possible to reduce or eliminate a possibility that the separated or isolated plane electrode 13 rides over and comes into contact with the two plane electrodes 21 having different potentials. Therefore, it is possible to provide the acoustic wave device 1 in which the short-circuit defect is further reduced or prevented.

In addition, it is preferable that the maximum distance D13ₘₐₓ (refer to FIG. 5B) between the two end portions of the plane electrode 13 is smaller than a minimum distance D2ₘᵢₙ (refer to FIG. 1C) of the distances between the two plane electrodes 12 having different potentials in the plurality of plane electrodes 12.

According to this configuration, even when the plane electrode 13 is separated or isolated from the piezoelectric substrate 10, the maximum distance D13ₘₐₓ of the plane electrode 13 is smaller than the minimum distance D2ₘᵢₙ. Therefore, it is possible to reduce or eliminate a possibility that the separated or isolated plane electrode 13 rides over and comes into contact with the two plane electrodes 12 having different potentials. Therefore, it is possible to provide the acoustic wave device 1 in which the short-circuit defect is further reduced or prevented.

### 2. Configurations of Piezoelectric Substrate 10, Functional Electrode 11, and Plane Electrode 12

FIG. 2A is a plan view and a sectional view schematically showing a first example of an acoustic wave resonator of the acoustic wave device 1 according to an example embodiment. In the drawing, a basic structure of an acoustic wave resonator 60 of the acoustic wave chip 3 is shown as an example. The acoustic wave resonator 60 shown in FIG. 2A is provided to describe a typical structure of the acoustic wave resonator of the acoustic wave chip 3, and the number and the length of electrode fingers of the electrode are not limited thereto.

The acoustic wave resonator 60 includes the piezoelectric substrate 10 and comb electrodes 60a and 60b.

As shown in FIG. 2A(a), a pair of comb electrodes 60a and 60b facing each other are provided on the piezoelectric substrate 10. The comb electrode 60a includes a plurality of electrode fingers 61a (first electrode fingers) parallel to each other, and a busbar electrode 62a (first busbar electrode) that connects one ends of the plurality of electrode fingers 61a to each other. In addition, the comb electrode 60b includes a plurality of electrode fingers 61b (second electrode fingers) parallel to each other, and a busbar electrode 62b (second busbar electrode) that connects one ends of the plurality of electrode fingers 61b to each other. The plurality of electrode fingers 61a and 61b extend along a direction orthogonal to an acoustic wave propagation direction (X-axis direction). The busbar electrode 62a and the busbar electrode 62b face each other with the electrode fingers 61a and 61b interposed therebetween. The comb electrodes 60a and 60b define an interdigital transducer (IDT) electrode 54.

Here, the functional electrode 11 shown in FIGS. 1A and 1C includes the plurality of electrode fingers 61a and the plurality of electrode fingers 61b. In addition, the plane electrode 12 shown in FIGS. 1A and 1C includes the busbar electrodes 62a and 62b.

The acoustic wave resonator 60 of the acoustic wave chip 3 may include reflectors in both ends of the IDT electrode 54 in the acoustic wave propagation direction (X-axis direction).

As shown in FIG. 2A(b), for example, the IDT electrode 54 has a multilayer structure including a close contact layer 540 and a main electrode layer 542.

The close contact layer 540 is a layer to improve close contact between the piezoelectric substrate 10 and the main electrode layer 542, and for example, Ti may be used as a material thereof. As a material of the main electrode layer 542, for example, Al including Cu by about 1% may be used, for example. A protection layer 55 is formed to cover the comb electrodes 60a and 60b. The protection layer 55 is a layer to protect the main electrode layer 542 from an outside environment, to adjust frequency temperature characteristics, and to improve humidity resistance, and for example, is a dielectric film including silicon dioxide as a main component.

Materials forming the close contact layer 540, the main electrode layer 542, and the protection layer 55 are not limited to the above-described materials. Furthermore, the IDT electrode 54 may have another structure other than the above-described multilayer structure. For example, the IDT electrode 54 may be formed of metal such as Ti, Al, Cu, Pt, Au, Ag, or Pd, or an alloy, or may include a plurality of multilayer bodies formed of the metal or the alloy described above. In addition, the protection layer 55 does not need to be formed.

Next, a multilayer structure of the piezoelectric substrate 10 will be described.

As shown in FIG. 2A(c), the piezoelectric substrate 10 includes a high acoustic velocity support substrate 51, a low acoustic velocity film 52, and a piezoelectric film 53, and has a structure in which the high acoustic velocity support substrate 51, the low acoustic velocity film 52, and the piezoelectric film 53 are laminated in this order.

For example, the piezoelectric film 53 is formed of a θ° Y-cut X propagation LiTaO₃ piezoelectric single crystal or piezoelectric ceramics (single crystal or ceramics through which the surface acoustic wave propagates in an X-axis direction, which is lithium tantalate single crystal or ceramics cut by a plane in which the X-axis is set as a central axis, and an axis rotated by θ° from the Y-axis is set as a normal line). A material and a cut-angle θ of the piezoelectric single crystal used as the piezoelectric film 53 are appropriately selected depending on required specifications of each filter.

The high acoustic velocity support substrate 51 supports the low acoustic velocity film 52, the piezoelectric film 53, and the IDT electrode 54. Furthermore, the high acoustic velocity support substrate 51 is a substrate in which the acoustic velocity of the bulk wave in the high acoustic velocity support substrate 51 is higher than the acoustic velocity of the acoustic wave of a surface acoustic wave or a boundary acoustic wave propagating through the piezoelectric film 53, and functions to prevent a surface acoustic wave from leaking down from the high acoustic velocity support substrate 51 by confining the surface acoustic wave in a portion at which the piezoelectric film 53 and the low acoustic velocity film 52 are laminated. As a material of the high acoustic velocity support substrate 51, for example, a piezoelectric body such as aluminum nitride, lithium tantalate, lithium niobate, or crystal, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, or a semiconductor such as silicon, or alternatively, a material having the above-described materials as the main components can be used. The above-described spinel includes an aluminum compound including one or more of Mg, Fe, Zn, and Mn, or oxygen. Examples of the above-described spinel can include MgAl₂O₄, FeAl₂O₄, ZnAl₂O₄, or MnAl₂O₄.

The low acoustic velocity film 52 is a film in which the acoustic velocity of the bulk wave in the low acoustic velocity film 52 is lower than that of the bulk wave propagating through the piezoelectric film 53, and is between the piezoelectric film 53 and the high acoustic velocity support substrate 51. This structure and a property that energy of an acoustic wave is essentially concentrated on a medium having a low acoustic velocity reduce or eliminate a possibility that surface acoustic wave energy leaks out from the IDT electrode. As a material of the low acoustic velocity film 52, for example, a dielectric such as a compound obtained by adding fluorine, carbon, or boron to glass, silicon oxide, silicon oxynitride, lithium oxide, tantalum oxide, or silicon oxide, or a material having the above-described materials as the main components can be used.

According to the above-described multilayer structure of the piezoelectric substrate 10, a Q value in a resonant frequency and an anti-resonant frequency can be significantly increased, compared to a structure in the related art in which the piezoelectric substrate may be used as a single layer. That is, since the acoustic wave resonator having a great Q value can be configured, a filter having a small insertion loss can be configured by using the acoustic wave resonator.

The high acoustic velocity support substrate 51 may have a structure in which a support substrate and a high acoustic velocity film having the higher acoustic velocity of the propagating bulk wave than that of the acoustic wave such as the surface acoustic wave or the boundary acoustic wave propagating through the piezoelectric film 53. In this case, as a material of the high acoustic velocity film, the same material as the material of the high acoustic velocity support substrate 51 can be used. As a material of the support substrate, for example, a piezoelectric body such as aluminum nitride, lithium tantalate, lithium niobate, or crystal, a ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, or a resin, and alternatively, a material having the above-described materials as the main components can be used.

In the present specification, the “main component of the material” means a component in which a ratio occupied by the material exceeds about 50% by weight, for example. The main component may exist in any one state of single crystal, polycrystal, or amorphous, or in a mixed state thereof.

FIG. 2B is a sectional view schematically showing a second example of the acoustic wave resonator of the acoustic wave device 1 according to the current example embodiment. In the acoustic wave resonator 60 shown in FIG. 2A, an example in which the IDT electrode 54 is formed on the piezoelectric substrate 10 having the piezoelectric film 53 has been described. However, as shown in FIG. 2B, the substrate on which the IDT electrode 54 is provided may be a piezoelectric single crystal substrate 57 including a single layer of the piezoelectric body layer.

For example, the piezoelectric single crystal substrate 57 includes a piezoelectric single crystal of LiNbO₃. The acoustic wave resonator according to this example includes the piezoelectric single crystal substrate 57 of LiNbO₃, the IDT electrode 54, and the protection layer 58 provided on the piezoelectric single crystal substrate 57 and on the IDT electrode 54.

The multilayer structure, the material, the cut-angle, and the thickness of the piezoelectric film 53 and the piezoelectric single crystal substrate 57 described above may be appropriately changed depending on the required bandpass characteristic of the acoustic wave filter device. The acoustic wave resonator using the LiTaO₃ piezoelectric substrate having another cut-angle other than the above-described cut-angle can achieve the same advantageous effect as that of the acoustic wave resonator 60 using the piezoelectric film 53 described above.

In addition, the piezoelectric substrate on which the IDT electrode 54 is provided may have a structure in which the support substrate, the energy confinement layer, and the piezoelectric film are laminated in this order. The IDT electrode 54 is provided on the piezoelectric film. As the piezoelectric film, for example, the LiTaO₃ piezoelectric single crystal or the piezoelectric ceramics may be used. The support substrate supports the piezoelectric film, the energy confinement layer, and the IDT electrode 54.

The energy confinement layer includes one layer or a plurality of layers, and the velocity of the bulk acoustic wave propagating through the at least one layer is higher than the velocity of the acoustic wave propagating in the vicinity of the piezoelectric film. For example, the energy confinement layer may have a multilayer structure having the low acoustic velocity layer and the high acoustic velocity layer. The low acoustic velocity layer is a film in which the acoustic velocity of the bulk wave in the low acoustic velocity layer is lower than the acoustic velocity of the acoustic wave propagating through the piezoelectric film. The high acoustic velocity layer is a film in which the acoustic velocity of the bulk wave in the high acoustic velocity layer is higher than the acoustic velocity of the acoustic wave propagating through the piezoelectric film. The support substrate may be used as the high acoustic velocity layer.

In addition, the energy confinement layer may be an acoustic impedance layer having a configuration in which a low acoustic impedance layer having a relatively low acoustic impedance and a high acoustic impedance layer having a relatively high acoustic impedance are alternately laminated.

It is preferable that the maximum distance D13ₘₐₓ (refer to FIG. 5B) between the two end portions of the plane electrode 13 is smaller than a minimum distance D4ₘᵢₙ (refer to FIG. 2A(b)) between the electrode finger 61a and the electrode finger 61b which are adjacent to each other.

According to this configuration, even when the plane electrode 13 is separated or isolated from the piezoelectric substrate 10, the maximum distance D13ₘₐₓ of the plane electrode 13 is smaller than the minimum distance D4ₘᵢₙ. Therefore, it is possible to reduce or eliminate a possibility that the separated or isolated plane electrode 13 rides over and comes into contact with two adjacent electrode fingers. Therefore, it is possible to provide the acoustic wave device 1 in which the short-circuit defect is further reduced or prevented.

In addition, FIG. 2C is a sectional view schematically showing a third example of the acoustic wave resonator of the acoustic wave device 1 according to the current example embodiment. FIG. 2C shows the bulk acoustic wave resonator as the acoustic wave resonator of the acoustic wave device 1. As shown in the drawing, for example, the bulk acoustic wave resonator includes a support substrate 65, a lower electrode 66, a piezoelectric body layer 67, and an upper electrode 68, and is configured so that the support substrate 65, the lower electrode 66, the piezoelectric body layer 67, and the upper electrode 68 are laminated in this order.

The support substrate 65 supports the lower electrode 66, the piezoelectric body layer 67, and the upper electrode 68, and is a silicon substrate, for example. In the support substrate 65, a cavity is provided in a region that comes into contact with the lower electrode 66. In this manner, the piezoelectric body layer 67 can freely vibrate.

The lower electrode 66 is provided on one surface of the support substrate 65. The upper electrode 68 is provided on one surface of the support substrate 65. As materials of the lower electrode 66 and the upper electrode 68, for example, Al including Cu by about 1% may be used, for example.

The piezoelectric body layer 67 is between the lower electrode 66 and the upper electrode 68. For example, the piezoelectric body layer 67 includes at least one of zinc oxide (ZnO), aluminum nitride (AlN), lead zirconate titanate (PZT), potassium niobate (KN), lithium niobate (LN), lithium tantalate (LT), quartz, and lithium borate (LiBO) as the main component.

The bulk acoustic wave resonator having the above-described multilayer configuration induces the bulk acoustic wave inside the piezoelectric body layer 67, and generates resonance by applying electric energy between the lower electrode 66 and the upper electrode 68. The bulk acoustic wave generated by the bulk acoustic wave resonator propagates between the lower electrode 66 and the upper electrode 68 in a direction perpendicular to a film surface of the piezoelectric body layer 67. That is, the bulk acoustic wave resonator is a resonator using the bulk acoustic wave.

Here, the functional electrode 11 shown in FIGS. 1A and 1C includes the lower electrode 66 and the upper electrode 68. In addition, the plane electrode 12 shown in FIGS. 1A and 1C includes a wiring electrode connected to the lower electrode 66 and a wiring electrode connected to the upper electrode 68. In addition, the piezoelectric substrate 10 shown in FIGS. 1A and 1C includes the support substrate 65. In addition, the piezoelectric substrate 10 does not need to have the piezoelectricity.

### 3. Manufacturing Method for Acoustic Wave Device 1

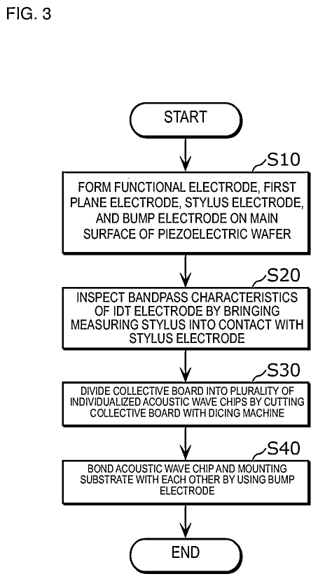

Next, an example of a manufacturing method for the acoustic wave device 1 according to the present example embodiment will be described. FIG. 3 is a flowchart showing the manufacturing method for the acoustic wave device 1.

First, the collective board 2 is manufactured by forming the functional electrode 11, the plurality of plane electrodes 12 (first plane electrodes) connected to the functional electrode 11, the plane electrode 43, and the plurality of bump electrodes 14 on a first main surface of a piezoelectric wafer 40 including the first main surface and the second main surface (S10).

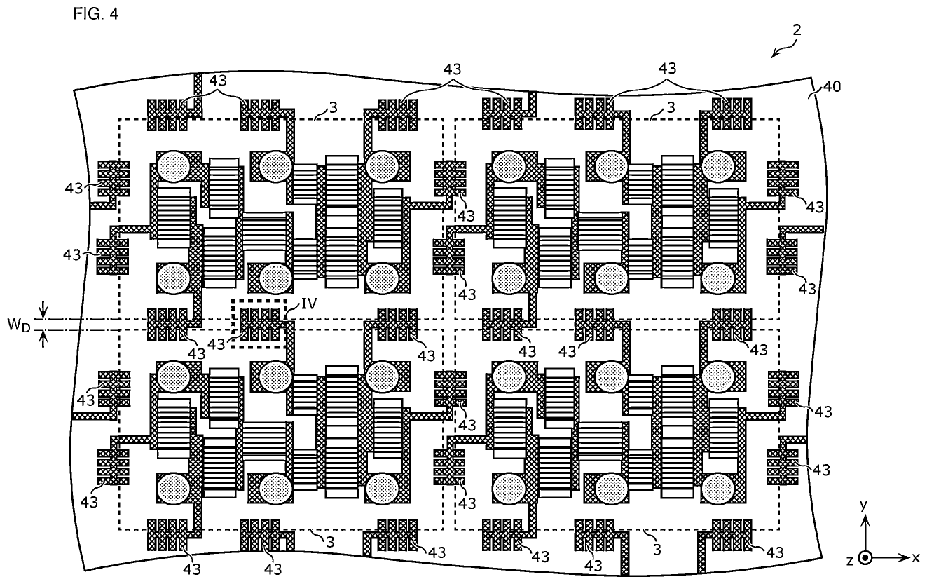

FIG. 4 is a plan view of the collective board 2 according to the current example embodiment. The drawing shows a partial electrode layout of the collective board 2 manufactured in the above-described electrode forming process. The collective board 2 includes a piezoelectric wafer 40, the plurality of functional electrodes 11, the plurality of plane electrodes 12, the plurality of plane electrodes 43, and the plurality of bump electrodes 14.

The piezoelectric wafer 40 has the piezoelectricity, and is a collective body of the piezoelectric substrate 10 before the piezoelectric substrate 10 is divided into individualized pieces. On the first main surface of the piezoelectric wafer 40, each of the functional electrode 11, the plane electrode 12, and the bump electrode 14 which define the acoustic wave chip 3 are arranged in a matrix form. In addition, the plane electrode 13 of the acoustic wave chip 3 after being divided into individualized pieces corresponds to the plane electrode 43 of the collective board 2.

As shown in FIG. 2A(c), the piezoelectric wafer 40 has a structure in which the high acoustic velocity support substrate, the low acoustic velocity film, and the piezoelectric film are laminated in this order. In addition, as shown in FIG. 2B, the piezoelectric wafer 40 may include the piezoelectric single crystal substrate. In addition, the piezoelectric wafer 40 may have a structure in which the support substrate, the energy confinement layer, and the piezoelectric film are laminated in this order.

The plane electrode 43 is an example of the stylus electrode, and is provided on a dicing line having a cutting W_{D} of the dicing line.

FIGS. 5A and 5B are views showing the plane electrode 43 in the vicinity of the dicing line of the collective board 2 and a configuration of the plane electrode 13 in the vicinity of an end side of the acoustic wave chip 3 according to the current example embodiment. Specifically, FIG. 5A shows a layout of the plane electrode 43 (in Process S10) before the dicing. In addition, FIG. 5B shows a layout of the plane electrode 13 (of the acoustic wave chip 3 after being divided into individualized pieces) after the dicing. FIG. 5A is an enlarged view of a region IV in FIG. 4.

As shown in FIG. 5A, in the collective board 2, the plane electrode 43 includes an electrode main body portion 71 and a slit portion 70. The slit portion 70 is formed between two electrode main body portions 71 adjacent to each other in the x-axis direction. The slit portion 70 is a region where a conductive material is not formed, is formed between the electrode main body portions 71 along a direction (y-axis direction) perpendicular to the dicing line, and is formed in both end portions in a direction (y-axis direction) perpendicular to the dicing line of the plane electrode 43.

In a process of manufacturing the collective board 2, the plane electrode 43 is formed so that the width of the slit portion 70 in a direction (x-axis direction) along the dicing line is smaller than a contact diameter of a tip of the measuring stylus (prober).

According to this configuration, the tip of the measuring stylus (prober) can ride over and come into contact with the plurality of electrode main body portions 71 of the plane electrode 43. Therefore, in a process of inspecting the bandpass characteristic of the IDT electrode of the collective board 2, the tip of the measuring stylus (prober) and the plane electrode 43 can be reliably and electrically connected to each other.

In addition, the plane electrode 43 is connected to the plane electrode 12 and the functional electrode 11 by using the extended wire 44. As shown in FIG. 5A, the extended wire 44 is connected to the plurality of electrode main body portions 71, is formed on the dicing line, and is formed within the predetermined cutting width W_{D} of the dicing line. In other words, the extended wire 44 is formed on the dicing line, and a width W_{L} of the extended wire 44 is smaller than the cutting width W_{D}.

According to this configuration, when the collective board 2 is cut along the dicing line with a dicing machine, and is divided into the plurality of individualized acoustic wave chips 3, the plane electrode 43 is in a state of not being connected to the functional electrode 11 and the plane electrode 12, and has no potential. Therefore, even when a portion (plane electrode 13) of the plane electrode 43 is separated after the dicing and comes into contact with the functional electrode 11 and the plane electrode 12, it is possible to reduce or prevent the short-circuit defect of the acoustic wave chip 3.

In addition, when the first main surface of the collective board 2 is viewed in a plan view, a portion of the slit portion 70 overlaps the cutting width W_{D} of the dicing line.

According to this configuration, as shown in FIG. 5B, when the collective board 2 is cut into the plurality of individualized acoustic wave chips 3 with the dicing machine, each of the plurality of electrode main body portions 71 forming one plane electrode 43 is in a separated state, and each of the plurality of electrode main body portions 71 is not connected to any electrode. In addition, in the completely manufactured acoustic wave device 1, even when a portion (plane electrode 13) of the plurality of electrode main body portions 71 remaining in the acoustic wave chip 3 is separated or isolated from the acoustic wave chip 3, each of the portions (plane electrodes 13) of the plurality of electrode main body portions 71 is an electrode obtained by subdividing the plane electrode 43. Therefore, it is possible to reduce or eliminate a possibility that the separated or isolated plane electrode rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

Next, the bandpass characteristic of the IDT electrode including the functional electrode 11 and the plurality of plane electrodes 12 is inspected by bringing the measuring stylus into contact with the plane electrode 43 (S20).

According to this configuration, before the acoustic wave chip 3 is face-down bonded to the mounting substrate 20, the bandpass characteristic of the IDT electrode is measured in the acoustic wave chip 3 alone. Therefore, since quality can be determined in a chip level, a yield of the acoustic wave device 1 serving as a finished product can be improved, and manufacturing efficiency can be improved.

The plurality of bump electrodes 14 do not need to be formed in a process of manufacturing the collective board 2, or may be formed after a process of inspecting the bandpass characteristic of the IDT electrodes (S20).

Next, the collective board 2 is divided into the plurality of individualized acoustic wave chips 3 through cutting with a dicing machine on the dicing line (S30).

As shown in FIG. 5B, after the dicing, the collective board 2 is divided into the plurality of individualized acoustic wave chips 3. In this case, a range of the cutting width W_{D} of the dicing is cut at a boundary between the adjacent acoustic wave chips 3. In this manner, the plane electrode 43 is divided into the plurality of plane electrodes 13.

Next, each of the plurality of individualized acoustic wave chips 3 is (face-down) bonded to the main surface 20a of the mounting substrate 20 on which the plurality of plane electrodes 21 is formed, by using the plurality of bump electrodes 14 (S40).

In Process S40 or after Process S40, the resin 30 may be formed to be in contact with the main surface 20a and to cover the acoustic wave chip 3.

Here, after Process S40, the maximum distance D13ₘₐₓ between the two end portions of each of the plurality of plane electrodes 13 is smaller than the minimum distance D1ₘᵢₙ of the distances between one of the plurality of plane electrodes 12 and one of the plurality of plane electrodes 21 which have potentials different from each other in the acoustic wave device 1.

According to this configuration, even when the plane electrode 13 is separated or isolated from the acoustic wave chip 3, the maximum distance D13ₘₐₓ of the plane electrode 13 is smaller than the minimum distance D1ₘᵢₙ. Therefore, it is possible to reduce or eliminate a possibility that the separated or isolated plane electrode 13 rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

In addition, the mounting substrate 20 used in Process S40 may be the mounting substrate 20 divided into individualized pieces corresponding to one acoustic wave chip 3, or may be the collective body of the mounting substrate 20 before the plurality of mounting substrates 20 are divided into individualized pieces. When the collective body of the mounting substrate 20 may be used, the collective body and the plurality of acoustic wave chips 3 may be bonded by using the plurality of bump electrodes 14. After the resin is provided, a collective component in which the collective body and the plurality of acoustic wave chips 3 are bonded may be cut into individualized pieces with the dicing machine to form an individual acoustic wave device.

After Process S40, the maximum distance D13ₘₐₓ between the two end portions of each of the plurality of plane electrodes 13 formed in an end portion of the acoustic wave chip 3 after the dicing may be smaller than a minimum distance Dbₘᵢₙ of the distances between the two bump electrodes having different potentials in the plurality of bump electrodes 14.

According to this configuration, even when the plane electrode 13 is separated or isolated from the acoustic wave chip 3, the maximum distance D13ₘₐₓ of the plane electrode 13 is smaller than the minimum distance Dbₘᵢₙ. Therefore, it is possible to reduce or eliminate a possibility that the separated or isolated plane electrode 13 rides over and comes into contact with the two bump electrodes 14 having different potentials. Therefore, it is possible to provide the acoustic wave device 1 in which the short-circuit defect is further reduced or prevented.

In addition, after Process S40, the maximum distance D13ₘₐₓ between the two end portions of each of the plurality of plane electrodes 13 formed in the end portion of the acoustic wave chip 3 after the dicing may be smaller than the minimum distance D3ₘᵢₙ of the distances between the two plane electrodes 21 having different potentials in the plurality of plane electrodes 21.

According to this configuration, even when the plane electrode 13 is separated or isolated from the piezoelectric substrate 10, the maximum distance D13ₘₐₓ of the plane electrode 13 is smaller than the minimum distance D3ₘᵢₙ. Therefore, it is possible to reduce or eliminate a possibility that the separated or isolated plane electrode 13 rides over and comes into contact with the two plane electrodes 21 having different potentials. Therefore, it is possible to provide the acoustic wave device 1 in which the short-circuit defect is further reduced or prevented.

In addition, after Process S40, the maximum distance D13ₘₐₓ between the two end portions of each of the plurality of plane electrodes 13 formed in the end portion of the acoustic wave chip 3 after the dicing may be smaller than the minimum distance D2ₘᵢₙ of the distances between the two plane electrodes 12 having different potentials in the plurality of plane electrodes 12.

According to this configuration, even when the plane electrode 13 is separated or isolated from the piezoelectric substrate 10, the maximum distance D13ₘₐₓ of the plane electrode 13 is smaller than the minimum distance D2ₘᵢₙ. Therefore, it is possible to reduce or eliminate a possibility that the separated or isolated plane electrode 13 rides over and comes into contact with the two plane electrodes 12 having different potentials. Therefore, it is possible to provide the acoustic wave device 1 in which the short-circuit defect is further reduced or prevented.

In addition, in Process S10, the maximum distance D13ₘₐₓ between the two end portions of each of the plurality of plane electrodes 13 formed in the end portion of the acoustic wave chip 3 after the dicing may be smaller than the minimum distance D4ₘᵢₙ of the distance between the electrode finger 61a and the electrode finger 61b which are adjacent to each other.

According to this configuration, even when the plane electrode 13 is separated or isolated from the piezoelectric substrate 10, the maximum distance D13ₘₐₓ of the plane electrode 13 is smaller than the minimum distance D4ₘᵢₙ. Therefore, it is possible to reduce or eliminate a possibility that the separated or isolated plane electrode 13 rides over and comes into contact with two adjacent electrode fingers. Therefore, it is possible to provide the acoustic wave device 1 in which the short-circuit defect is further reduced or prevented.

### 4. Configuration of Acoustic Wave Device According to Comparative Example

Here, a configuration of an acoustic wave device (in the related art) according to a comparative example will be described. The acoustic wave device according to the comparative example is different from the acoustic wave device 1 according to the present example embodiment in a configuration of the plane electrode 45 formed on the dicing line in a process of forming the IDT electrode. Hereinafter, with regard to the acoustic wave device and a manufacturing method therefor according to the comparative example, the same points as those of the acoustic wave device 1 and the manufacturing method therefor according to the present example embodiment will be omitted in the description, and different points will be mainly described.

A manufacturing method for an acoustic wave device according to a comparative example includes (1) a process of manufacturing a collective board 200 by forming the functional electrode, the plurality of first plane electrodes connected to the functional electrode, the plane electrode 45 provided on the dicing line having a predetermined cutting width, and the plurality of bump electrodes on a main surface of a piezoelectric wafer, (2) a process of inspecting the bandpass characteristic of the IDT electrode including the functional electrode and the plurality of first plane electrodes by bringing the measuring stylus into contact with the plane electrode 45, (3) a process of dividing the collective board 200 into the plurality of individualized acoustic wave chips 203 by cutting the collective board 200 on the dicing line with the dicing machine after inspecting the bandpass characteristic of the IDT electrode, and (4) a process of face-down bonding the plurality of bump electrodes of each of the plurality of individualized acoustic wave chips 203 to the third main surface of the mounting substrate on which the plurality of second plane electrodes are formed.

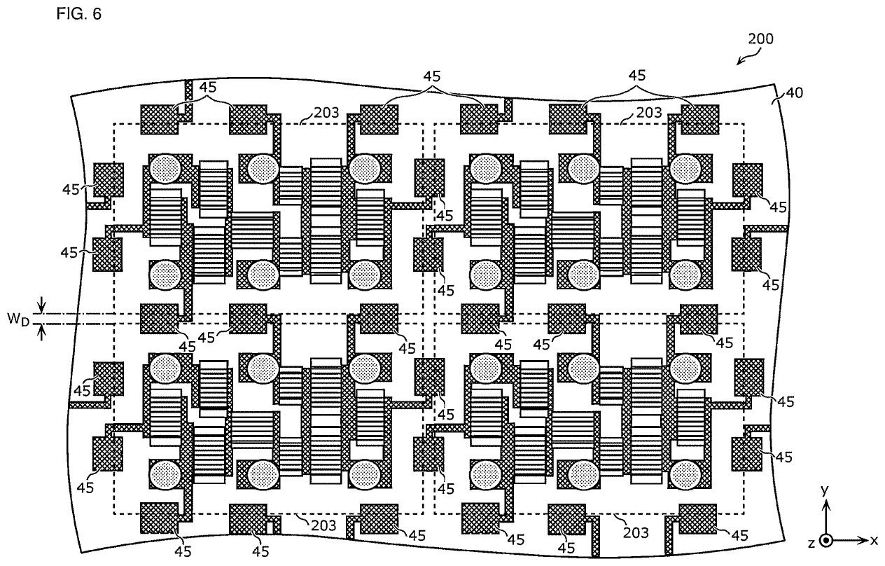

FIG. 6 is a plan view of a collective board 200 according to the comparative example. The drawing shows a partial electrode layout of the collective board 200 manufactured in a process of manufacturing the collective board 200. The collective board 200 includes the piezoelectric wafer 40, the plurality of functional electrodes 11, the plurality of plane electrodes 12, and the plurality of plane electrodes 45.

The plane electrode 45 is an example of the stylus electrode, and is provided on the dicing line having the cutting width W_{D}. As shown in FIG. 6, in the collective board 200, the plane electrode 45 has a rectangular or substantially rectangular shape in a plan view of the collective board 200, and the width in a direction (y-axis direction) perpendicular to the dicing line is larger than the cutting width W_{D} of the dicing.

After the collective board 200 is cut with the dicing machine, the collective board 200 is divided into the plurality of individualized acoustic wave chips 203. In this case, a range of the cutting width W_{D} is cut at a boundary between the adjacent acoustic wave chips 203. In this manner, a portion of the plane electrode 45 remains on an end side of the individualized acoustic wave chip 203.

Here, a size of the portion of the plane electrode 45 remaining in the individualized acoustic wave chip 203 is not specified. Therefore, in some cases, the maximum distance between the two end portions of the remaining plane electrode 45 is equal to or larger than the minimum distance D1ₘᵢₙ of the distances between one of the plurality of plane electrodes 12 and one of the plurality of plane electrodes 21 which have potentials different from each other in the acoustic wave device according to the comparative example.

According to this configuration, when a portion of the remaining plane electrode 45 is isolated from the acoustic wave chip 203, there is a possibility that the maximum distance of the portion of the remaining plane electrode 45 is equal to or larger than the minimum distance D1ₘᵢₙ. Therefore, there is a possibility that the portion of the isolated plane electrode 45 rides over and comes into contact with the plane electrode 12 and the plane electrode 21 to cause a short-circuit defect of the functional electrode 11. Therefore, in the acoustic wave device according to the comparative example, an occurrence of the short-circuit defect cannot be reduced or prevented.

In contrast, according to the acoustic wave device 1 and the manufacturing method therefor according to the present example embodiment, even when the plane electrode 13 remaining in the individualized acoustic wave chip 3 is separated or isolated from the acoustic wave chip 3, the maximum distance D13ₘₐₓ of the plane electrode 13 is smaller than the minimum distance D1ₘᵢₙ. Therefore, it is possible to reduce or eliminate a possibility that the separated or isolated plane electrode 13 rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

### 5. Advantageous Effects

As described above, the acoustic wave device 1 according to the present example embodiment includes the piezoelectric substrate 10 having piezoelectricity, and including the main surfaces 10a and 10b, the mounting substrate 20 including the main surfaces 20a and 20b, with the main surface 20a facing the main surface 10a, the functional electrode 11 provided on the main surface 10a, and performing electromechanical conversion with the piezoelectric substrate 10, the plurality of plane electrodes 12 provided on the main surface 10a, and connected to the functional electrode 11, the plurality of plane electrodes 21 provided on the main surface 20a, the plane electrode 13 provided on the main surface 10a to be in contact with the end side of the piezoelectric substrate 10, and not connected to the functional electrode 11 and the plane electrode 12, and the plurality of bump electrodes 14 bonded to the main surfaces 10a and 20a. The maximum distance D13ₘₐₓ between the two end portions of the plane electrode 13 is smaller than the minimum distance D1ₘᵢₙ of the distances between one of the plurality of plane electrodes 12 and one of the plurality of plane electrodes 21 which have potentials different from each other.

According to this configuration, even when the plane electrode 13 is separated or isolated from the piezoelectric substrate 10, the maximum distance D13ₘₐₓ of the plane electrode 13 is smaller than the minimum distance D1ₘᵢₙ. Therefore, it is possible to reduce or eliminate a possibility that the separated or isolated plane electrode 13 rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

In addition, the acoustic wave device 1 according to the present example embodiment includes the piezoelectric substrate 10 having piezoelectricity, and including the main surfaces 10a and 10b, the mounting substrate 20 including the main surfaces 20a and 20b, with the main surface 20a facing the main surface 10a, the functional electrode 11 provided on the main surface 10a, and performing electromechanical conversion with the piezoelectric substrate 10, the plurality of plane electrodes 12 provided on the main surface 10a, and connected to the functional electrode 11, the plurality of plane electrodes 21 provided on the main surface 20a, the plane electrode 13 provided on the main surface 10a to be in contact with the end side of the piezoelectric substrate 10, and not connected to the functional electrode 11 and the plane electrode 12, and the plurality of bump electrodes 14 bonded to the main surfaces 10a and 20a. The maximum distance D13ₘₐₓ between the two end portions of the plane electrode 13 is smaller than the minimum distance Dbₘᵢₙ of the distances between the two bump electrodes 14 having different potentials in the plurality of bump electrodes 14.

According to this configuration, even when the plane electrode 13 is separated or isolated from the piezoelectric substrate 10, the maximum distance D13ₘₐₓ of the plane electrode 13 is smaller than the minimum distance Dbₘᵢₙ. Therefore, it is possible to reduce or eliminate a possibility that the separated or isolated plane electrode 13 rides over and comes into contact with the two bump electrodes 14 having different potentials. Therefore, it is possible to provide the acoustic wave device 1 in which the short-circuit defect is reduced or prevented.

In addition, for example, in the acoustic wave device 1, the maximum distance D13ₘₐₓ between the two end portions of the plane electrode 13 is smaller than the minimum distance D3ₘᵢₙ of the distances between the two plane electrodes 21 having different potentials in the plurality of plane electrodes 21.

According to this configuration, even when the plane electrode 13 is separated or isolated from the piezoelectric substrate 10, the maximum distance D13ₘₐₓ of the plane electrode 13 is smaller than the minimum distance D3ₘᵢₙ. Therefore, it is possible to reduce or eliminate a possibility that the separated or isolated plane electrode 13 rides over and comes into contact with the two plane electrodes 21 having different potentials. Therefore, it is possible to provide the acoustic wave device 1 in which the short-circuit defect is further reduced or prevented.

In addition, for example, in the acoustic wave device 1, the maximum distance D13ₘₐₓ between the two end portions of the plane electrode 13 is smaller than the minimum distance D2ₘᵢₙ of the distances between the two plane electrodes 12 having different potentials in the plurality of plane electrodes 12.

According to this configuration, even when the plane electrode 13 is separated or isolated from the piezoelectric substrate 10, the maximum distance D13ₘₐₓ of the plane electrode 13 is smaller than the minimum distance D2ₘᵢₙ. Therefore, it is possible to reduce or eliminate a possibility that the separated or isolated plane electrode 13 rides over and comes into contact with the two plane electrodes 12 having different potentials. Therefore, it is possible to provide the acoustic wave device 1 in which the short-circuit defect is further reduced or prevented.

In addition, for example, the acoustic wave device 1 includes the IDT electrode 54 provided on the main surface 10a. The IDT electrode 54 includes the plurality of electrode fingers 61a and 61b parallel or substantially parallel to each other, the busbar electrode 62a configured to connect one ends of the plurality of electrode fingers 61a to each other, and the busbar electrode 62b configured to connect one ends of the plurality of electrode fingers 61b, and facing the busbar electrode 62a with the plurality of electrode fingers 61a and 61b interposed therebetween. Here, the functional electrode 11 includes the plurality of electrode fingers 61a and 61b, and the plurality of plane electrodes 12 include the busbar electrodes 62a and 62b.

According to this configuration, it is possible to reduce or eliminate a possibility that the separated or isolated plane electrode 13 rides over and comes into contact with the busbar electrode 62a or 62b and the plane electrode 21 to cause a short-circuit defect of the functional electrode 11. Therefore, it is possible to provide the acoustic wave device 1 in which the short-circuit defect is reduced or prevented.

In addition, for example, in the acoustic wave device 1, the maximum distance D13ₘₐₓ between the two end portions of the plane electrode 13 is smaller than the minimum distance D4ₘᵢₙ between the adjacent electrode finger 61a and the electrode finger 61b.

In addition, the manufacturing method for the acoustic wave device 1 according to the present example embodiment includes a process (S10) of manufacturing the collective board 2 by forming the functional electrode 11 performing electromechanical conversion with the piezoelectric wafer 40 having piezoelectricity and including the main surfaces 10a and 10b, the plurality of plane electrodes 12 connected to the functional electrode 11, the plane electrode 43 provided on the dicing line having the predetermined cutting width W_{D}, and the plurality of bump electrodes 14, on the main surface 10a of the piezoelectric wafer 40, a process (S20) of inspecting the bandpass characteristic of the IDT electrode 54 including the functional electrode 11 and the plurality of plane electrodes 12 by bringing the measuring stylus into contact with the plane electrode 43, a process (S30) of dividing the collective board 2 into the plurality of individualized acoustic wave chips 3 by cutting the collective board 2 along the dicing line with the cutting machine after inspecting the bandpass characteristic of the IDT electrode 54, and a process (S40) of bonding the plurality of bump electrodes 14 of each of the plurality of individualized acoustic wave chips 3 to the main surface 20a on which the plurality of plane electrodes 21 of the mounting substrate 20 are formed. In the process of manufacturing the collective board 2, the plane electrode 43 includes the slit portions 70 connected to the functional electrode 11, and having no conductive material formed in both end portions in the direction perpendicular to the dicing line. When the collective board 2 is viewed in a plan view, a portion of the slit portion 70 overlaps the dicing line.

According to this configuration, when the collective board 2 is cut with the dicing machine and is divided into the plurality of individualized acoustic wave chips 3, each of portions of the plurality of electrode main body portions 71 of one plane electrode 43 is in a separated state, and each of the plurality of electrode main body portions 71 is not connected to any electrode. In addition, in the completely manufactured acoustic wave device 1, even when a portion of the plurality of electrode main body portions 71 remaining in the acoustic wave chip 3 is separated or isolated from the acoustic wave chip 3, each of the portions of the plurality of electrode main body portions 71 is an electrode obtained by subdividing the plane electrode 43. Therefore, it is possible to reduce or eliminate a possibility that the separated or isolated plane electrode rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

In addition, for example, in the process of manufacturing the collective board 2 in the manufacturing method for the acoustic wave device 1, the plane electrode 43 is connected to the functional electrode 11 by using the extended wire 44 formed on the dicing line, and the extended wire 44 is formed within a range of the cutting width W_{D} of the dicing line.

According to this configuration, when the collective board 2 is cut along the dicing line with a dicing machine, and is divided into the plurality of individualized acoustic wave chips 3, the plane electrode 43 is in a state of not being connected to the functional electrode 11 and the plane electrode 12, and has no potential. Therefore, even when the plane electrode 13 which is a portion of the plane electrode 43 after the dicing is separated, rides over, and comes into contact with the functional electrode 11 and/or the plane electrode 12, it is possible to reduce or prevent a short-circuit defect of the acoustic wave chip 3.

In addition, for example, in the manufacturing method for the acoustic wave device 1, in the process of manufacturing the collective board 2, the plane electrode 43 is formed so that the width of the slit portion 70 in a direction along the dicing line is smaller than the contact diameter of the tip of the measuring stylus.

According to this configuration, the tip of the measuring stylus rides over and comes into contact with the plurality of electrode main body portions 71 of the plane electrode 43. Therefore, in the process of inspecting the bandpass characteristics of the IDT electrode 54 of the collective board 2, the tip of the measuring stylus and the plane electrode 43 can be reliably and electrically connected to each other.

In addition, for example, in the manufacturing method for the acoustic wave device 1, in dividing the plane electrode 43 into the plurality of individualized acoustic wave chips 3, the plane electrode 43 is divided into the plurality of plane electrodes 13 through cutting with a dicing machine. After the process of bonding each of the plurality of acoustic wave chips 3 and the mounting substrate 20 to each other, the maximum distance D13ₘₐₓ between the two end portions of each of the plurality of plane electrodes 13 is smaller than the minimum distance D1ₘᵢₙ of distances from one of the plurality of plane electrodes 12 and one of the plurality of plane electrodes 21 which have potentials different from each other.

According to this configuration, even when the plane electrode 13 is separated or isolated from the acoustic wave chip 3, the maximum distance D13ₘₐₓ of the plane electrode 13 is smaller than the minimum distance D1ₘᵢₙ. Therefore, it is possible to reduce or eliminate a possibility that the separated or isolated plane electrode 13 rides over and comes into contact with the plane electrode 12 and the plane electrode 21 to cause a short-circuit defect of the functional electrode 11. Therefore, it is possible to provide the acoustic wave device 1 in which the short-circuit defect is reduced or prevented.

In addition, for example, in the manufacturing method for the acoustic wave device 1, after the process of bonding each of the plurality of acoustic wave chips 3 and the mounting substrate 20 to each other, the maximum distance D13ₘₐₓ between the two end portions of each of the plurality of plane electrodes 13 is smaller than the minimum distance Dbₘᵢₙ of the distances between the two bump electrodes 14 having different potentials in the plurality of bump electrodes 14.

According to this configuration, even when the plane electrode 13 is separated or isolated from the acoustic wave chip 3, the maximum distance D13ₘₐₓ of the plane electrode 13 is smaller than the minimum distance Dbₘᵢₙ. Therefore, it is possible to reduce or eliminate a possibility that the separated or isolated plane electrode 13 rides over and comes into contact with the two bump electrodes 14 having different potentials. Therefore, it is possible to provide the acoustic wave device 1 in which the short-circuit defect is further reduced or prevented.

In addition, for example, in the manufacturing method for the acoustic wave device 1, after the process of bonding each of the plurality of acoustic wave chips 3 and the mounting substrate 20 to each other, the maximum distance D13ₘₐₓ between the two end portions of each of the plurality of plane electrodes 13 is smaller than the minimum distance D3ₘᵢₙ of the distances between the two plane electrodes 21 having different potentials in the plurality of plane electrodes 21.

According to this configuration, even when the plane electrode 13 is separated or isolated from the piezoelectric substrate 10, the maximum distance D13ₘₐₓ of the plane electrode 13 is smaller than the minimum distance D3ₘᵢₙ. Therefore, it is possible to reduce or eliminate a possibility that the separated or isolated plane electrode 13 rides over and comes into contact with the two plane electrodes 21 having different potentials. Therefore, it is possible to provide the acoustic wave device 1 in which the short-circuit defect is further reduced or prevented.

In addition, for example, in the manufacturing method for the acoustic wave device 1, after the process of bonding each of the plurality of acoustic wave chips 3 and the mounting substrate 20 to each other, the maximum distance D13ₘₐₓ between the two end portions of each of the plurality of plane electrodes 13 is smaller than the minimum distance D2ₘᵢₙ of the distances between the two plane electrodes 12 having different potentials in the plurality of plane electrodes 12.

According to this configuration, even when the plane electrode 13 is separated or isolated from the piezoelectric substrate 10, the maximum distance D13ₘₐₓ of the plane electrode 13 is smaller than the minimum distance D2ₘᵢₙ. Therefore, it is possible to reduce or eliminate a possibility that the separated or isolated plane electrode 13 rides over and comes into contact with the two plane electrodes 12 having different potentials. Therefore, it is possible to provide the acoustic wave device 1 in which the short-circuit defect is further reduced or prevented.

In addition, for example, in the manufacturing method for the acoustic wave device 1, after the process of dividing the collective board 2 into the plurality of individualized acoustic wave chips 3, the maximum distance D13ₘₐₓ between the two end portions of each of the plurality of plane electrodes 13 is smaller than the minimum distance D4ₘᵢₙ of the distances between the electrode finger 61a and the electrode finger 61b which are adjacent to each other.

According to this configuration, even when the plane electrode 13 is separated or isolated from the piezoelectric substrate 10, the maximum distance D13ₘₐₓ of the plane electrode 13 is smaller than the minimum distance D4ₘᵢₙ. Therefore, it is possible to reduce or eliminate a possibility that the separated or isolated plane electrode 13 rides over and comes into contact with two adjacent electrode fingers. Therefore, it is possible to provide the acoustic wave device 1 in which the short-circuit defect is further reduced or prevented.

### OTHER EXAMPLE EMBODIMENTS

Hitherto, acoustic wave devices and manufacturing methods therefor according to the present invention have been described with reference to the example embodiments. However, the present invention is not limited to the above-described example embodiments. The present invention also includes modification examples obtained by applying various modifications to the above-described example embodiments within the scope not departing from the concept of the present invention, and various types of equipment in which the acoustic wave device according to example embodiments of the present invention is incorporated.

In addition, for example, in the acoustic wave devices according to the above-described example embodiments, a matching element such as an inductor and a capacitor, and a switch circuit may be connected between the respective configuration elements.

The IDT electrode includes the plurality of first electrode fingers and the plurality of second electrode fingers parallel or substantially parallel to each other, the first busbar electrode configured to connect one ends of the plurality of first electrode fingers to each other, and the second busbar electrode configured to connect one ends of the plurality of second electrode fingers to each other, and facing the first busbar electrode with the plurality of first electrode fingers and the plurality of second electrode fingers interposed therebetween.

The functional electrode includes the plurality of first electrode fingers and the plurality of second electrode fingers.

After the process of dividing the collective board into the plurality of individualized acoustic wave chips, the maximum distance connecting the two end portions of each of the plurality of third plane electrodes is smaller than the minimum distance of the distances between one of the plurality of first electrode fingers and one of the plurality of second electrode fingers which are adjacent to each other.

Example embodiments of the present invention can be widely used in communication equipment such as mobile phones as small acoustic wave devices in which a short-circuit defects is reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate having piezoelectricity, and including a first main surface and a second main surface;
a second substrate including a third main surface and a fourth main surface facing the third main surface;
a functional electrode provided on the first main surface to perform electromechanical conversion with the first substrate;
a plurality of first plane electrodes provided on the first main surface and connected to the functional electrode;
a plurality of second plane electrodes provided on the third main surface;
a third plane electrode provided on the first main surface to be in contact with an end side of the first substrate and not connected to the functional electrode and the first plane electrode; and
a plurality of bump electrodes bonded to the first main surface and the third main surface; wherein
a maximum distance between two end portions of the third plane electrode is smaller than a minimum distance of distances between one of the plurality of first plane electrodes and one of the plurality of second plane electrodes which have potentials different from each other.

2. The acoustic wave device according to claim 1, wherein the maximum distance between two end portions of the third plane electrode is smaller than a minimum distance of distances between two of the plurality of bump electrodes having different potentials.

3. The acoustic wave device according to claim 1, wherein the maximum distance between two end portions of the third plane electrode is smaller than a minimum distance of distances between two of the plurality of second plane electrodes having different potentials.

4. The acoustic wave device according to claim 1, wherein the maximum distance between two end portions of the third plane electrode is smaller than a minimum distance between two of the plurality of first plane electrodes having different potentials.

5. The acoustic wave device according to claim 1, wherein
the acoustic wave device includes an IDT electrode provided on the first main surface;
the IDT electrode includes:
a plurality of first electrode fingers and a plurality of second electrode fingers parallel or substantially parallel to each other;
a first busbar electrode to connect one ends of the plurality of first electrode fingers to each other; and
a second busbar electrode connecting one ends of the plurality of second electrode fingers to each other and facing the first busbar electrode with the plurality of first electrode fingers and the plurality of second electrode fingers interposed therebetween;
the functional electrode includes the plurality of first electrode fingers and the plurality of second electrode fingers; and
the plurality of first plane electrodes include the first busbar electrode and the second busbar electrode.

6. The acoustic wave device according to claim 5, wherein the maximum distance between two end portions of the third plane electrode is smaller than a minimum distance between one of the plurality of first electrode fingers and one of the plurality of second electrode fingers which are adjacent to each other.

7. An acoustic wave device comprising:
a first substrate having piezoelectricity, and including a first main surface and a second main surface;
a second substrate including a third main surface and a fourth main surface facing the third main surface;
a functional electrode provided on the first main surface to perform electromechanical conversion with the first substrate;
a plurality of first plane electrodes provided on the first main surface and connected to the functional electrode;
a plurality of second plane electrodes provided on the third main surface;
a third plane electrode provided on the first main surface to be in contact with an end side of the first substrate, and not connected to the functional electrode and the first plane electrode; and
a plurality of bump electrodes bonded to the first main surface and the third main surface; wherein
a maximum distance between two end portions of the third plane electrode is smaller than a minimum distance of distances between two of the plurality of bump electrodes having different potentials.

8. The acoustic wave device according to claim 7, wherein the maximum distance between two end portions of the third plane electrode is smaller than a minimum distance of distances between two of the plurality of second plane electrodes having different potentials.

9. The acoustic wave device according to claim 7, wherein the maximum distance between two end portions of the third plane electrode is smaller than a minimum distance between two of the plurality of first plane electrodes having different potentials.

10. The acoustic wave device according to claim 7, wherein
the acoustic wave device includes an IDT electrode provided on the first main surface;
the IDT electrode includes:
a plurality of first electrode fingers and a plurality of second electrode fingers parallel or substantially parallel to each other;
a first busbar electrode to connect one ends of the plurality of first electrode fingers to each other; and
a second busbar electrode connecting one ends of the plurality of second electrode fingers to each other and facing the first busbar electrode with the plurality of first electrode fingers and the plurality of second electrode fingers interposed therebetween;
the functional electrode includes the plurality of first electrode fingers and the plurality of second electrode fingers; and
the plurality of first plane electrodes include the first busbar electrode and the second busbar electrode.

11. The acoustic wave device according to claim 10, wherein the maximum distance between two end portions of the third plane electrode is smaller than a minimum distance between one of the plurality of first electrode fingers and one of the plurality of second electrode fingers which are adjacent to each other.

12. A manufacturing method for an acoustic wave device, the method comprising:
manufacturing a collective board by forming a functional electrode to perform electromechanical conversion with a piezoelectric wafer having piezoelectricity and including a first main surface and a second main surface, a plurality of first plane electrodes connected to the functional electrode, a stylus electrode provided on a dicing line with a predetermined cutting width, and a plurality of bump electrodes, on the first main surface of the piezoelectric wafer;
inspecting a bandpass characteristic of an IDT electrode including the functional electrode and the plurality of first plane electrodes by bringing a measuring stylus into contact with the stylus electrode;
dividing the collective board into a plurality of individualized acoustic wave chips by cutting the collective board along the dicing line with a dicing machine after inspecting the bandpass characteristic of the IDT electrode; and
bonding the plurality of bump electrodes of each of the plurality of individualized acoustic wave chips to a third main surface on which a plurality of second plane electrodes of a mounting substrate are formed; wherein
in manufacturing the collective board, the stylus electrode includes slit portions connected to the functional electrode, and no conductive material is formed in both end portions in a direction perpendicular to the dicing line; and
a portion of the slit portion overlaps the dicing line when the collective board is viewed in a plan view.

13. The manufacturing method for the acoustic wave device according to claim 12, wherein in manufacturing the collective board, the stylus electrode is connected to the functional electrode by using an extended wire formed on the dicing line, and the extended wire is formed within a range of the predetermined cutting width of the dicing line.

14. The manufacturing method for an acoustic wave device according to claim 12, wherein in manufacturing the collective board, the stylus electrode is formed so that a width of the slit portion in a direction along the dicing line is smaller than a contact diameter of a tip of the measuring stylus.

15. The manufacturing method for an acoustic wave device according to claim 12, wherein in dividing the collective board into the plurality of individualized acoustic wave chips, the stylus electrode is divided into a plurality of third plane electrodes through cutting with a dicing machine, and after bonding each of the plurality of acoustic wave chips and the mounting substrate to each other, a maximum distance between two end portions of each of the plurality of third plane electrodes is smaller than a minimum distance between one of the plurality of first plane electrodes and one of the plurality of second plane electrodes which have potentials different from each other.

16. The manufacturing method for an acoustic wave device according to claim 12, wherein in dividing the collective board into the plurality of individualized acoustic wave chips, the stylus electrode is divided into a plurality of third plane electrodes through cutting with a dicing machine, and after bonding each of the plurality of acoustic wave chips and the mounting substrate to each other, a maximum distance between two end portions of each of the plurality of third plane electrodes is smaller than a minimum distance of distances between two bump electrodes having different potentials in the plurality of bump electrodes.

17. The manufacturing method for an acoustic wave device according to claim 15, wherein after bonding each of the plurality of acoustic wave chips and the mounting substrate to each other, a maximum distance between two end portions of each of the plurality of third plane electrodes is smaller than a minimum distance between two of the plurality of second plane electrodes having different potentials.

18. The manufacturing method for an acoustic wave device according to claim 15, wherein after bonding each of the plurality of acoustic wave chips and the mounting substrate to each other, a maximum distance between two end portions of each of the plurality of third plane electrodes is smaller than a minimum distance between two of the plurality of first plane electrodes having different potentials.

19. The manufacturing method for an acoustic wave device according to claim 15, wherein
in dividing the collective board into the plurality of individualized acoustic wave chips, each of the plurality of acoustic wave chips includes an IDT electrode provided on the first main surface;
the IDT electrode includes:
a plurality of first electrode fingers and a plurality of second electrode fingers parallel or substantially parallel to each other;
a first busbar electrode connecting one ends of the plurality of first electrode fingers to each other; and
a second busbar electrode connecting one ends of the plurality of second electrode fingers to each other and facing the first busbar electrode with the plurality of first electrode fingers and the plurality of second electrode fingers interposed therebetween;
the functional electrode includes the plurality of first electrode fingers and the plurality of second electrode fingers; and
after dividing the collective board into the plurality of individualized acoustic wave chips, a maximum distance to connect two end portions of each of the plurality of third plane electrodes is smaller than a minimum distance between one of the plurality of first electrode fingers and one of the plurality of second electrode fingers which are adjacent to each other.
